(19) United States
(12) Patent Application Publication
(10) Pub. No.: US 2012/0024338 A1
(43) Pub. Date: Feb. 2, 2012

(54) Back Contact Formation

(76) Inventors: Pratima V. Addepalli, Monroe, MI (US); John S. Deeken, Toledo, OH (US); Oleh P. Karpenko, Perrysburg, OH (US)

(21) Appl. No.: 13/185,597

(22) Filed: Jul. 19, 2011

Related U.S. Application Data
(60) Provisional application No. 61/366,403, filed on Jul. 21, 2010.

(51) Int. Cl. H01L 31/042; H01L 31/0224

(52) U.S. Cl. 136/244; 136/256; 438/98; 257/E31.126

(57) ABSTRACT

A photovoltaic cell may include a carbon residue and a copper ion on a cadmium telluride layer.

### BACK CONTACT INFORMATION

This application claims priority under 35 U.S.C. §119(e) to Provisional Application No. 61/366,403, filed on Jul. 21, 2010, which is incorporated herein by reference.

### TECHNICAL FIELD

This invention relates to photovoltaic cells and methods of production.

### BACKGROUND

A photovoltaic cell may include a back contact metal to create electrical contact for the cell. Traditional methods of controlling deposition and composition of the back contact metal have been inefficient.

### DESCRIPTION OF DRAWINGS

FIG. 1 is a schematic of a multilayered structure.

FIG. 2 is a schematic of a photovoltaic cell having multiple layers.

FIG. 3 is a schematic of a photovoltaic cell having multiple layers.

FIG. 4 is a schematic of a photovoltaic cell having multiple layers.

### DETAILED DESCRIPTION

Photovoltaic cells can include multiple layers created on a substrate (or superstrate). For example, a photovoltaic cell can include a barrier layer, a transparent conductive oxide (TCO) layer, a buffer layer, a semiconductor window layer, and a semiconductor absorber layer, formed in a stack on a substrate. Each layer may in turn include more than one layer or film. For example, the semiconductor window layer and semiconductor absorber layer together can be considered a semiconductor layer. The semiconductor layer can include a first film created (for example, formed or deposited) on the TCO layer and a second film created on the first film. Additionally, each layer can cover all or a portion of the cell and/or all or a portion of the layer or substrate underlying the layer. For example, a “layer” can mean any amount of any material that contacts all or a portion of a surface.

Following deposition of the semiconductor window and absorber layers, a back contact metal can be deposited to serve as an electrical contact. Back contact composition plays an important role in cell performance. The surface of the preceding semiconductor absorber layer may be treated prior to deposition of the back contact layer to improve composition of the back contact. Current methods of cleaning the semiconductor surface are not sufficient to remove all organic and inorganic material. The workflow through the manufacturing process also adds more variation. During storage, submodules can absorb organic material from the plant environment, allowing air to oxidize. Such absorption can change the composition of the back contact. The semiconductor absorber layer may undergo one or more treatment steps to facilitate subsequent deposition and formation of the back contact layer.

For example, a carbon-containing layer can be applied to the surface of the semiconductor absorber layer, which may include any suitable semiconductor absorber material, including, for example, a cadmium telluride. The carbon-containing layer may be applied in a controlled fashion. The carbon-containing layer may include any suitable carbon source, including, for example, an emulsified wax, any suitable water-soluble material, as well as any suitable large organic molecule. Smaller water-soluble molecules may also be suitable. A dopant, such as a copper ion, may be applied. The dopant may be complexed with a large ligand. The complexed copper may be used as the carbon source, or a separate source of carbon may be used. Examples of appropriate ligands include iminopyrazine, pyridyl and bipyridyl ligands, and polyoxy compounds (i.e., polyethers). The structure of the complexed dopant may have a cage structure, in which case the formed compounds may be similar in structure to phthalocyanine or polyporphyrin dyes. The formed compounds may be stable under typical photovoltaic cell conditions.

The methods and configurations discussed herein may be used to fabricate one or more multilayer structures which may be used during manufacturing of one or more photovoltaic cells. Such devices may be grouped with one or more additional photovoltaic cells and incorporated into a photovoltaic module. For example, photovoltaic cells (or multilayer structures) fabricated consistent with the aforementioned configurations may be incorporated into multiple submodules, which may be assembled into larger photovoltaic modules. Such modules may by incorporated into various systems for generating electricity. For example, a photovoltaic module may include one or more submodules consisting of multiple photovoltaic cells connected in series. One or more submodules may be connected in parallel via a shared cell to form a photovoltaic module. A bus bar assembly may be attached to a contact surface of the module to enable connection to additional electrical components (e.g., one or more additional modules). For example, a first strip of double-sided tape may be distributed along a length of the module, and a first lead foil may be applied adjacent thereto. A second strip of double-sided tape (smaller than the first strip) may be applied adjacent to the first lead foil. A second lead foil may be applied adjacent to the second strip of double-sided tape. The tape and lead foils may be positioned such that at least one portion of the first lead foil is exposed, and at least one portion of the second lead foil is exposed. Following application of the tape and lead foils, a plurality of bus bars may be positioned along the contact region of the module. The bus bars may be positioned parallel from one another, at any suitable distance apart. For example, the plurality of bus bars may include at least one bus bar positioned on a portion of the first lead foil, and at least one bus bar positioned on a portion of the second lead foil. The bus bar, along with the portion of lead foil on which it has been applied, may define a positive or negative region. A roller may be used to create a loop in a section of the first or second lead foil. The loop may be threaded through the hole of a subsequently deposited back glass. The photovoltaic module may be connected to other electronic components, including, for example, one or more additional photovoltaic modules. For example, the photovoltaic module may be electrically connected to one or more additional photovoltaic modules to form a photovoltaic array.

The photovoltaic cells/modules/arrays may be included in a system for generating electricity. For example, a photovoltaic cell may be illuminated with a beam of light to generate a photocurrent. The photocurrent may be collected and converted from direct current (DC) to alternating current (AC) and distributed to a power grid. Light of any suitable wavelength may be directed at the cell to produce the photocurrent, including, for example, more than 400 nm, or less than 700 nm (e.g., ultraviolet light). Photocurrent generated from a photovoltaic cell may be combined with photocurrent generated from other photovoltaic cells. For example, the photovoltaic cells may be part of one or more photovoltaic modules in a photovoltaic array, from which the aggregate current may be harnessed and distributed.

In one aspect, a method of forming a layered structure can include forming a transparent conductive oxide layer adjacent to a substrate, forming a semiconductor window layer adjacent to the transparent conductive oxide layer, forming a semiconductor absorber layer adjacent to the semiconductor window layer, and forming a layer including a carbon and copper complex adjacent to the semiconductor absorber layer.

The complex can include an emulsified wax. The complex can include a water-soluble material. The complex can include a carbon source that is a ligand for the copper. The ligand can include an iminopyrazine, a pyridyl ligand, a bipyridyl ligand, or a polyoxy compound.

The method can include complexing the ligand and the copper to form the complex adjacent to the semiconductor absorber layer. Complexing the ligand and copper can include forming a cage structure including the ligand and the copper. Forming a cage structure can include forming a structure substantially similar to a phthalocyanine dye. Forming a cage structure can include forming a structure substantially similar to a polyporphyrin dye. The method can include combining an iron-containing material with the copper. The method can include forming a back contact adjacent to the complex. The method can include forming a back support adjacent to the back contact.

In another aspect, a method of forming a layered structure can include forming a transparent conductive oxide layer adjacent to a substrate, forming a semiconductor window layer adjacent to the transparent conductive oxide layer, forming a semiconductor absorber layer adjacent to the semiconductor window layer, complexing a copper ion with a ligand to form a copper complex, and forming a layer of the copper complex adjacent to the semiconductor absorber layer. The complexing can include associating the copper ion with a compound including an iminopyrazine, a pyridyl ligand, a bipyridyl ligand, or a polyoxy compound.

In one aspect, a multilayer structure can include a substrate, a transparent conductive oxide layer adjacent to the substrate, a semiconductor window layer adjacent to the transparent conductive oxide layer, a semiconductor absorber layer adjacent to the semiconductor window layer, and a layer including a carbon and copper complex adjacent to the semiconductor absorber layer.

The complex can include emulsified wax. The complex can include an iminopyrazine. The complex can include a pyridyl ligand. The complex can include a bipyridyl ligand. The complex layer can include a polyoxy compound. The complex can include a phthalocyanine. The complex can include a polyporphyrin. The complex can include a carbon-containing ligand and a copper ion complexed in a cage structure. The semiconductor absorber layer can include cadmium telluride. The multilayer structure can include a back contact adjacent to the semiconductor absorber layer. The multilayer structure can include a back support adjacent to the back contact.

In one aspect, a multilayer structure may include a substrate. The multilayer structure may include a transparent conductive oxide layer adjacent to the substrate. The multilayer structure may include a semiconductor window layer adjacent to the transparent conductive oxide layer. The multilayer structure may include a semiconductor absorber layer adjacent to the semiconductor window layer. The multilayer structure may include a layer including a copper complex adjacent to the semiconductor absorber layer. The copper complex may include an iminopyrazine, a pyridyl ligand, a bipyridyl ligand, or a polyoxy compound.

In one aspect, a photovoltaic module may include a plurality of photovoltaic cells. Each one of the plurality of photovoltaic cells may include a substrate. Each one of the plurality of photovoltaic cells may include a transparent conductive oxide layer adjacent to the substrate. Each one of the plurality of photovoltaic cells may include a semiconductor window layer adjacent to the transparent conductive oxide layer. Each one of the plurality of photovoltaic cells may include a semiconductor absorber layer adjacent to the semiconductor window layer. Each one of the plurality of photovoltaic cells may include a contact layer including a carbon and copper complex adjacent to the semiconductor absorber layer. The photovoltaic module may include at least one conductor electrically connected to the contact layer and configured to conduct a photocurrent generated in the module. The complex may include an emulsified wax, an iminopyrazine, a pyridyl ligand, a bipyridyl ligand, a polyoxy compound, a phthalocyanine, a polyporphyrin, or a carbon-containing ligand and a copper ion complexed in a caged structure.

In one aspect, a method for generating electricity may include illuminating a photovoltaic cell with a beam of light to generate a photocurrent. The method may include collecting the generated photocurrent. The photovoltaic cell may include a substrate. The photovoltaic cell may include a transparent conductive oxide layer adjacent to the substrate. The photovoltaic cell may include a semiconductor window layer adjacent to the transparent conductive oxide layer. The photovoltaic cell may include a semiconductor absorber layer adjacent to the semiconductor window layer. The photovoltaic cell may include a contact layer. The contact layer may include a carbon and copper complex adjacent to the semiconductor absorber layer.

The beam of light may include a wavelength of more than 400 nm. The beam of light may include a wavelength of less than 700 nm. The beam of light may include ultraviolet light. The beam of light may include blue light. The beam of light may include white light. The complex may include an emulsified wax, an iminopyrazine, a pyridyl ligand, a bipyridyl ligand, a polyoxy compound, a phthalocyanine, a polyporphyrin, or a carbon-containing ligand and a copper ion complexed in a caged structure. The method may include converting the photocurrent from DC to AC. The method may include combining the generated photocurrent with a photocurrent generated from another photovoltaic cell.

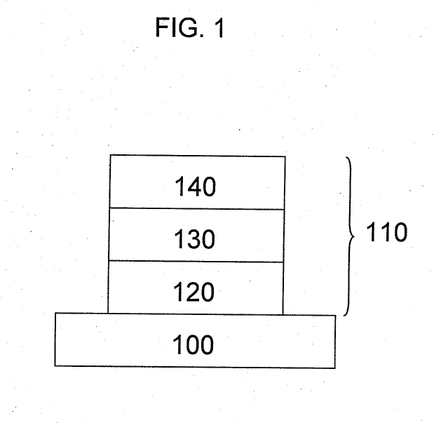

Referring to FIG. 1, by way of example, barrier layer 120 may be deposited onto substrate 100. Substrate 100 may include any suitable material, including, for example, a glass. The glass may include a soda-lime glass, or any glass with reduced iron content. The glass may undergo a treatment step, during which one or more edges of the glass may be substantially rounded. The glass may have any suitable transmittance, including about 450 nm to about 800 nm. The glass may also have any suitable transmission percentage, including, for example, more than about 50%, more than about 60%, more than about 70%, more than about 80%, or more than about 85%. For example, substrate 100 may include a glass with about 90% transmittance.

Barrier layer 120 may include any suitable material, including, for example, silicon aluminum oxide. Barrier layer 120 can be incorporated between the substrate and the TCO layer to lessen diffusion of sodium or other contaminants from the substrate to the semiconductor layers, which could result in degradation or delamination. Barrier layer 120 can be transparent, thermally stable, with a reduced number of pin holes and having high sodium-blocking capability, and good adhesive properties. Barrier layer 120 can include any suitable number of layers and may have any suitable thickness, including, for example, more than about 500 A, more than about 750 A, or less than about 1200 A. For example, barrier layer 120 may have a thickness of about 1000 A.

A transparent conductive oxide layer 130 can be formed adjacent to barrier layer 120. Transparent conductive oxide layer 130 may be deposited using any suitable means, including, for example, sputtering. Transparent conductive oxide layer 130 may be sputtered from a sputter target including any suitable sputter material, including, for example, a combination of cadmium and tin. Transparent conductive oxide layer 130 may include any suitable material, including, for example, an amorphous layer of cadmium stannate. Transparent conductive oxide layer 130 may have any suitable thickness, including, for example, more than about 2000 A, more than about 2500 A, or less than about 3000 A. For example, transparent conductive oxide layer 130 may have a thickness of about 2600 A.

A buffer layer 140 may be formed onto transparent conductive oxide layer 130. Buffer layer 140 can be deposited between the TCO layer and a semiconductor window layer to decrease the likelihood of irregularities occurring during the formation of the semiconductor window layer. Buffer layer 140 may include any suitable material, including, for example, an amorphous tin oxide. Buffer layer 140 can include any other suitable material, including zinc tin oxide, zinc oxide, and zinc magnesium oxide. Buffer layer 140 may have any suitable thickness, including, for example, more than about 500 A, more than about 650 A, more than about 800 A, or less than about 1200 A. For example, buffer layer 140 may have a thickness of about 900 A. Buffer layer 140 may be deposited using any suitable means, including, for example, sputtering. For example, buffer layer 140 may include a tin oxide sputtered in the presence of an oxygen gas. Buffer layer 140, along with barrier layer 120 and transparent conductive oxide layer 130, can form transparent conductive oxide stack 110.

The layers included in the structure and photovoltaic cell can be created using any suitable technique or combination of techniques. For example, the layers can be formed by low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis. Each deposition layer can be of any suitable thickness, for example in the range of about 1 to about 5000 A.

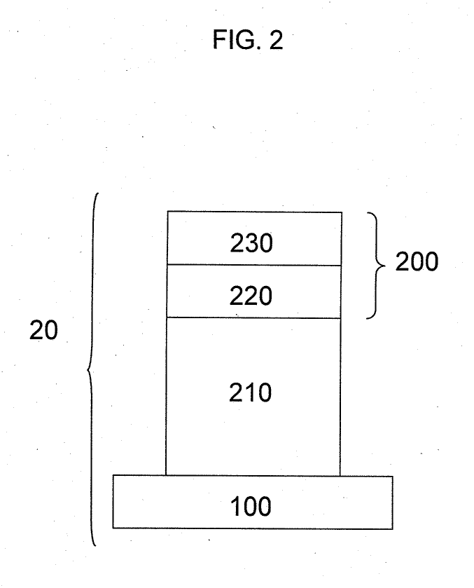

Following deposition, transparent conductive oxide stack 110 can be annealed to form annealed stack 210 from FIG. 2, which can lead to formation of cadmium stannate. Transparent conductive oxide stack 110 can be annealed using any suitable annealing process. The annealing can occur in the presence of a gas selected to control an aspect of the annealing, for example, nitrogen gas. Transparent conductive oxide stack 110 can be annealed under any suitable pressure, for example, under reduced pressure, in a low vacuum, or at about 0.01 Pa (10⁻⁴ Torr). Transparent conductive oxide stack 110 can be annealed at any suitable temperature or temperature range. For example, transparent conductive oxide stack 110 can be annealed above about 380 degrees C., above about 400 degrees C., above about 500 degrees C., above about 600 degrees C., or below about 800 degrees C. For example, transparent conductive oxide stack 110 can be annealed at about 400 degrees C. to about 800 degrees C. or about 500 degrees C. to about 700 degrees C. Transparent conductive oxide stack 110 can be annealed for any suitable duration. Transparent conductive oxide stack 110 can be annealed for more than about 10 minutes, more than about 20 minutes, more than about 30 minutes, or less than about 40 minutes. For example, transparent conductive oxide stack 110 can be annealed for about 15 to about 20 minutes.

Annealed transparent conductive oxide stack 210 can be used to form photovoltaic cell 20 from FIG. 2. Referring to FIG. 2, a semiconductor layer 200 can be deposited onto annealed transparent conductive oxide stack 210. Semiconductor layer 200 can include a semiconductor window layer 220 and a semiconductor absorber layer 230. Semiconductor window layer 220 can be deposited directly onto annealed transparent conductive oxide stack 210. Semiconductor window layer 220 can be deposited using any known deposition technique, including vapor transport deposition. Semiconductor absorber layer 230 can be deposited onto semiconductor window layer 220. Semiconductor absorber layer 230 can be deposited using any known deposition technique, including vapor transport deposition. Semiconductor window layer 220 can include a cadmium sulfide layer. Semiconductor absorber layer 230 can include a cadmium telluride layer.

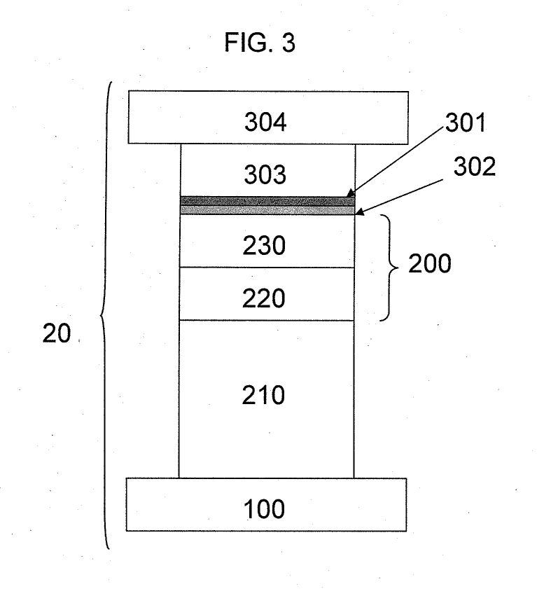

Referring now to FIG. 3, semiconductor absorber layer 230 may undergo one or more treatment steps, prior to deposition of a back contact metal. For example, a carbon-containing layer 302 can be applied from a carbon source. The carbon source leading to the formation of carbon residue 302 can include any suitable substance, including, for example, an emulsified wax, any suitable water-soluble molecule, or any suitable large organic molecule. A dopant 301 may also be deposited on semiconductor absorber layer 230. Dopant 301 may include a copper, including, for example, any suitable copper ion. Dopant 301 may include an iron-containing substance in conjunction with a copper ion. Dopant 301 may be complexed with any suitable ligand, including, for example, iminopyrazine, pyridyl and bipyridyl ligands, or any suitable polyoxy compound. Nitrogen-containing aromatic compounds such as pyridines and pyrroles can be suitable complexing agents.

Dopant 301 may consist of structures linked together to form a cage structure. The structure of dopant 301 can be substantially similar in structure to phthalocyanine and polyporphyrin dyes. Following surface treatment of semiconductor absorber layer 230, a back contact layer 303 may be deposited. Back contact layer 303 may contain any suitable material, including, for example, molybdenum. Back contact layer 303 may be deposited using any suitable deposition technique, including, for example, sputtering. The carbon residue and dopant deposited onto semiconductor absorber layer 230 may lead to an improved deposition and composition of back contact layer 303. Following deposition of back contact layer 303, a back support 304 may be deposited. Back support 304 may include any suitable material, including, for example, a glass, including, for example, a soda-lime glass.

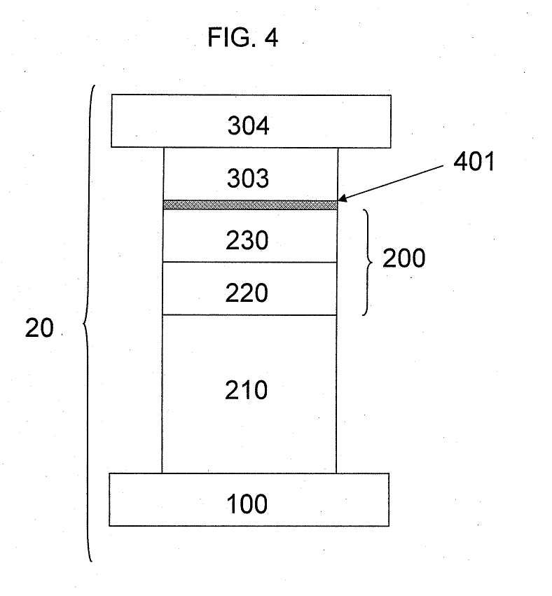

The dopant may also include the source for the carbon residue. Referring to FIG. 4, by way of example, a carbon residue 401 may be deposited on semiconductor absorber layer 230. Carbon-containing layer 401 may contain a carbon source, which may also include a dopant. The dopant may include any suitable material, including, for example, copper, such as any suitable copper ion. The dopant may also include an iron-containing material. The dopant may include a copper ion in conjunction with an iron-containing substance. The dopant may be complexed with any suitable ligand, including, for example, iminopyrazine, pyridyl and bipyridyl ligands, and any suitable polyoxy compound. Following surface treatment of semiconductor absorber layer 230, a back contact layer 303 may be deposited. Back contact layer 303 may contain any suitable material, including, for example, molybdenum. Back contact layer 303 may be deposited using any suitable deposition technique, including, for example, sputtering. The carbon residue and dopant deposited onto semiconductor absorber layer 230 may lead to an improved deposition and composition of back contact layer 303. Following deposition of back contact layer 303, a back support 304 may be deposited. Back support 304 may include any suitable material, including, for example, a glass, including, for example, a soda-lime glass.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A method of forming a layered structure, comprising:
forming a transparent conductive oxide layer adjacent to a substrate;
forming a semiconductor window layer adjacent to the transparent conductive oxide layer;
forming a semiconductor absorber layer adjacent to the semiconductor window layer; and
forming a layer comprising a carbon and copper complex adjacent to the semiconductor absorber layer.

2. The method of claim 1, wherein the complex comprises an emulsified wax.

3. The method of claim 1, wherein the complex comprises a water-soluble material.

4. The method of claim 1, wherein the complex comprises a carbon source that is a ligand for the copper.

5. The method of claim 4, wherein the ligand is selected from the group consisting of an iminopyrazine, a pyridyl ligand, a bipyridyl ligand, and a polyoxy compound.

6. The method of claim 4, further comprising complexing the ligand and the copper to form the complex adjacent to the semiconductor absorber layer.

7. The method of claim 6, wherein complexing the ligand and copper comprises forming a cage structure comprising the ligand and copper.

8. The method of claim 7, wherein forming a cage structure comprises forming a structure substantially similar to a phthalocyanine dye.

9. The method of claim 7, wherein forming a cage structure comprises forming a structure substantially similar to a polyporphyrin dye.

10. The method of claim 1, further comprising combining an iron-containing material with the copper.

11. The method of claim 1, further comprising forming a back contact adjacent to the complex.

12. The method of claim 11, further comprising forming a back support adjacent to the back contact.

13. A method of forming a layered structure, comprising:
forming a transparent conductive oxide layer adjacent to a substrate;
forming a semiconductor window layer adjacent to the transparent conductive oxide layer;
forming a semiconductor absorber layer adjacent to the semiconductor window layer;
complexing a copper ion with a ligand to form a copper complex; and
forming a layer of the copper complex adjacent to the semiconductor absorber layer.

14. The method of claim 13, wherein the complexing comprises associating the copper ion with a compound selected from the group consisting of an iminopyrazine, a pyridyl ligand, a bipyridyl ligand, and a polyoxy compound.

15. A multilayer structure comprising:
a substrate;
a transparent conductive oxide layer adjacent to the substrate;
a semiconductor window layer adjacent to the transparent conductive oxide layer;
a semiconductor absorber layer adjacent to the semiconductor window layer;
and a layer comprising a carbon and copper complex adjacent to the semiconductor absorber layer.

16. The multilayer structure of claim 15, wherein the complex comprises emulsified wax.

17. The multilayer structure of claim 15, wherein the complex comprises an iminopyrazine.

18. The multilayer structure of claim 15, wherein the complex comprises a pyridyl ligand.

19. The multilayer structure of claim 15, wherein the complex comprises a bipyridyl ligand.

20. The multilayer structure of claim 15, wherein the complex comprises a polyoxy compound.

21. The multilayer structure of claim 15, wherein the complex comprises a phthalocyanine.

22. The multilayer structure of claim 15, wherein the complex comprises a polyporphyrin.

23. The multilayered structure of claim 15, wherein the complex comprises a carbon-containing ligand and a copper ion complexed in a cage structure.

24. The multilayer structure of claim 15, wherein the semiconductor absorber layer comprises cadmium telluride.

25. The multilayer structure of claim 15, further comprising a back contact adjacent to the semiconductor absorber layer.

26. The multilayer structure of claim 15, further comprising a back support adjacent to the back contact.

27. A multilayer structure comprising:
a substrate;
a transparent conductive oxide layer adjacent to the substrate;
a semiconductor window layer adjacent to the transparent conductive oxide layer;
a semiconductor absorber layer adjacent to the semiconductor window layer; and
a layer comprising a copper complex adjacent to the semiconductor absorber layer.

28. The multilayer structure of claim 27, wherein the copper complex comprises an iminopyrazine, a pyridyl ligand, a bipyridyl ligand, or a polyoxy compound.

29. A photovoltaic module comprising:
a plurality of photovoltaic cells, each one of the plurality of photovoltaic cells comprising:
a substrate;
a transparent conductive oxide layer adjacent to the substrate;
a semiconductor window layer adjacent to the transparent conductive oxide layer;
a semiconductor absorber layer adjacent to the semiconductor window layer; and
a contact layer comprising a carbon and copper complex adjacent to the semiconductor absorber layer.

30. The photovoltaic module of claim 29, further comprising:
at least one conductor electrically connected to the contact layer and configured to conduct a photocurrent generated in the module.

31. The photovoltaic module of claim 29, wherein the complex comprises an emulsified wax, an iminopyrazine, a pyridyl ligand, a bipyridyl ligand, a polyoxy compound, a phthalocyanine, a polyporphyrin, or a carbon-containing ligand and a copper ion complexed in a caged structure.

32. A method for generating electricity, the method comprising:
illuminating a photovoltaic cell with a beam of light to generate a photocurrent; and
collecting the generated photocurrent, wherein the photovoltaic cell comprises:
a substrate;
a transparent conductive oxide layer adjacent to the substrate;
a semiconductor window layer adjacent to the transparent conductive oxide layer;
a semiconductor absorber layer adjacent to the semiconductor window layer; and
a contact layer comprising a carbon and copper complex adjacent to the semiconductor absorber layer.

33. The method of claim 32, wherein the beam of light comprises a wavelength of more than 400 nm.

34. The method of claim 32, wherein the beam of light comprises a wavelength of less than 700 nm.

35. The method of claim 32, wherein the beam of light comprises ultraviolet light.

36. The method of claim 32 wherein the beam of light comprises blue light.

37. The method of claim 32, wherein the beam of light comprises white light.

38. The method of any one of claims 32-37, wherein the complex comprises an emulsified wax, an iminopyrazine, a pyridyl ligand, a bipyridyl ligand, a polyoxy compound, a phthalocyanine, a polyporphyrin, or a carbon-containing ligand and a copper ion complexed in a caged structure.

39. The method of any one of claims 32-38, further comprising converting the photocurrent from DC to AC.

40. The method of any one of claims 32-39, further comprising combining the generated photocurrent with a photocurrent generated from another photovoltaic cell.
